(19) United States
(12) Patent Application Publication
(10) Pub. No.: US 2022/0364770 A1
(43) Pub. Date: Nov. 17, 2022

(54) MULTI-REFRIGERATION-CYCLE APPARATUS

(71) Applicants: EBARA CORPORATION, Tokyo (JP); EBARA REFRIGERATION EQUIPMENT & SYSTEMS CO., LTD., Tokyo (JP)

(72) Inventors: Motoshi KOHAKU, Tokyo (JP); Yukihiro FUKUSUMI, Tokyo (JP); Nobutaka BANNAI, Tokyo (JP); Hiromasa MIYATA, Tokyo (JP)

(73) Assignees: EBARA CORPORATION, Toyko (JP); EBARA REFRIGERATION EQUIPMENT & SYSTEMS CO., LTD., Toyko (JP)

(21) Appl. No.: 17/736,865

(22) Filed: May 4, 2022

(30) Foreign Application Priority Data
May 12, 2021 (JP) 2021-080878
May 12, 2021 (JP) 2021-080879

(51) Int. Cl. F25B 7/00

(52) U.S. Cl. CPC F25B 7/00

(57) ABSTRACT

A multi-refrigeration-cycle apparatus capable of reducing an installation area for equipment installed in a sub-fab and capable of shortening a pipe for delivering a cooling medium to a semiconductor-device manufacturing equipment is disclosed. The multi-refrigeration-cycle apparatus includes: a first refrigeration cycle having a first refrigerant for performing heat exchange with a cooling medium for cooling the semiconductor-device manufacturing equipment, the first refrigerant circulating in the first refrigeration cycle; and a second refrigeration cycle having a second refrigerant for performing heat exchange with the first refrigerant, the second refrigerant circulating in the second refrigeration cycle. At least a part of the first refrigeration cycle is arranged in a clean room where the semiconductor-device manufacturing equipment is installed, and the second refrigeration cycle is arranged in a sub-fab.

### CROSS REFERENCE TO RELATED APPLICATION

This document claims priorities to Japanese Patent Application No. 2021-080878 filed May 12, 2021 and Japanese Patent Application No. 2021-080879 filed May 12, 2021, the entire contents of which are hereby incorporated by reference.

### BACKGROUND

In order to expand a memory capacity, multilayered structure is developing as a technological innovation for 3D-NAND. Due to the multilayered structure, a processing time required for an etching process is increasing, and a decrease in production capability (or throughput) has become an issue. In order to shorten the etching time and improve the throughput, it is effective to cool a processing chamber of an etching equipment to a low temperature in a range of about −30° C. to −120° C.

Therefore, in order to achieve a low temperature of about −30° C. to −120° C., a refrigeration apparatus, such as a dual-refrigeration-cycle apparatus, has been conventionally used and commercially provided by a plurality of companies.

However, the dual-refrigeration-cycle apparatus requires the increased number of structural elements, as compared with a single-refrigeration-cycle apparatus, and requires the increased number of pipes connecting these structural elements accordingly. Therefore, it is inevitable that overall dimensions of the apparatus increase. FIG. 10 shows a typical installation situation of a semiconductor-device manufacturing equipment, which includes a processing chamber (for example, a processing chamber of an etching equipment) for processing a semiconductor device. This processing chamber is installed in a clean room, while a dual-refrigeration-cycle apparatus for cooling the processing chamber is installed in an area called a sub-fab, which is a sub-fabrication where various peripheral equipment are installed. This sub-fub is an area different from the clean room.

In most cases, the positional relationship between the clean room and the sub-fab is such that the clean room is located upstairs and the sub-fub is located downstairs. In principle, an installation area for equipment in the sub-fab cannot exceed an installation area for the semiconductor-device manufacturing equipment upstairs. In addition, since there are many devices installed in the sub-fab, reducing the installation area of the sub-fab is a basic issue for various devices. However, the number of layers of the multilayered structure in the semiconductor-device manufacturing equipment tends to increase, and the size of the dual-refrigeration-cycle apparatus is expected to increase in the future.

In addition to the above issues, pipes for delivering an ultra-low temperature cooling medium needs to be covered with a thick cold insulating material for preventing dew condensation and for heat insulation, which entails time-consuming constructions and increases costs. Furthermore, a space is required for installing such pipes over a long distance from the sub-fab to the clean room. The longer the pipes, the more likely a temperature of an ambient atmosphere is transferred to a cooling medium in the pipes (i.e., the cooling effect is lowered).

Further, the temperature of the cooling medium that has been used for cooling the semiconductor-device manufacturing equipment varies greatly according to a process, and the temperature of the cooling medium in the refrigeration apparatus also tends to fluctuate accordingly. As a result, the operation of the refrigeration apparatus may become unstable, and the semiconductor-device manufacturing equipment may not be cooled properly.

### SUMMARY

Therefore, there is provided a multi-refrigeration-cycle apparatus capable of reducing an installation area for equipment installed in a sub-fab and capable of shortening a pipe for delivering a cooling medium to a semiconductor-device manufacturing equipment.

Further, there is provided a multi-refrigeration-cycle apparatus capable of achieving stable operation and appropriately cooling a semiconductor-device manufacturing equipment.

Embodiments, which will be described below, relate to a multi-refrigeration-cycle apparatus including a low-temperature-side refrigeration cycle and a high-temperature-side refrigeration cycle, and more particularly to a multi-refrigeration-cycle apparatus for use in cooling a semiconductor-device manufacturing equipment, such as an etching equipment.

In an embodiment, there is provided a multi-refrigeration-cycle apparatus for cooling a semiconductor-device manufacturing equipment, comprising: a first refrigeration cycle having a first refrigerant for performing heat exchange with a cooling medium for cooling the semiconductor-device manufacturing equipment, the first refrigerant circulating in the first refrigeration cycle; and a second refrigeration cycle having a second refrigerant for performing heat exchange with the first refrigerant, the second refrigerant circulating in the second refrigeration cycle, wherein at least a part of the first refrigeration cycle is arranged in a clean room where the semiconductor-device manufacturing equipment is installed, and the second refrigeration cycle is arranged in a sub-fab.

According to the above-described embodiment, components of the multi-refrigeration-cycle apparatus are divided into two parts that are arranged in the clean room and the sub-fab, respectively. Therefore, the installation area for equipment installed in the sub-fab can be reduced.

Furthermore, since at least a part of the first refrigeration cycle is arranged in the clean room, the cooling pipe for transferring the cooling medium having an ultra-low temperature from the first refrigeration cycle to the semiconductor-device manufacturing equipment (for example, a processing chamber of an etching equipment) can be shortened. As a result, a space for the cooling pipe can be small and a cooling efficiency can be improved.

In an embodiment, the entire first refrigeration cycle is located in the clean room.

According to the above-described embodiment, the installation area in the sub-fab can be further reduced.

In an embodiment, the first refrigeration cycle includes: a first evaporator configured to perform heat exchange between the cooling medium and the first refrigerant to generate the first refrigerant in a gas phase; a first compressor configured to compress the first refrigerant in the gas phase; a first condenser configured to condense the compressed first refrigerant in the gas phase to generate the first refrigerant in a liquid phase; and a first expansion mechanism located between the first condenser and the first evaporator and configured to reduce pressure and temperature of the first refrigerant. The first evaporator and the first expansion mechanism are arranged in the clean room, and the first compressor and the first condenser are arranged in the sub-fab.

According to the above-described embodiment, the first compressor and the first condenser are arranged in the sub-fab located downstairs, and the first evaporator and the first expansion mechanism are arranged in the clean room located upstairs. With this arrangement, a lubricating oil leaked from the first compressor into the first refrigerant does not stay in the first evaporator, and the lubricating oil can be returned to the first compressor by its gravity.

In an embodiment, the multi-refrigeration-cycle apparatus further comprises an intermediate-medium circulation line configured to circulate an intermediate medium between the first refrigeration cycle and the second refrigeration cycle, the intermediate-medium circulation line extending between the first refrigeration cycle and the second refrigeration cycle.

According to the above-described embodiment, the first refrigerant in the first refrigeration cycle and the second refrigerant in the second refrigeration perform the heat cycle exchange via the intermediate medium. A fluid, which is easier to handle than the first refrigerant and the second refrigerant, can be used as the intermediate medium as long as the heat of the first refrigerant can be transferred to the second refrigerant. Therefore, a flexible and inexpensive pipe, such as resin tube, can be used for the intermediate-medium circulation line. As a result, a manufacturing cost can be reduced, and moreover a degree of freedom in the arrangement of the first refrigeration cycle and the second refrigeration cycle is increased. Further, since the temperature of the intermediate medium (for example, 0° C. to −80° C.) is higher than the temperature of the refrigerant (for example, −30° C. to −120° C.), a cold insulating material covering the medium circulation line may be a simple one, as compared with a cold insulating material covering the cooling pipe.

The intermediate medium has a thermal capacity corresponding to its volume. Therefore, the intermediate medium functions as a thermal buffer between the first refrigerant and the second refrigerant. Generally, the temperature of the cooling medium that has been used for cooling the semiconductor-device manufacturing equipment varies, and the temperature of the first refrigerant tends to fluctuate accordingly. Since the intermediate medium can absorb such fluctuations of the temperature of the first refrigerant, the operation of the multi-refrigeration-cycle apparatus can be stable. As a result, the multi-refrigeration-cycle apparatus can supply the cooling medium having a stable temperature to the semiconductor-device manufacturing equipment.

In an embodiment, the multi-refrigeration-cycle apparatus further comprises a buffer tank coupled to the intermediate-medium circulation line.

According to the above-described embodiment, the thermal capacity of the intermediate medium can be increased, and the operation of the multi-refrigeration-cycle apparatus can be more stable.

In an embodiment, the intermediate medium is brine (antifreeze).

According to the above-described embodiment, a flexible and inexpensive pipe, such as resin tube, can be used for the intermediate-medium circulation line. As a result, a manufacturing cost can be reduced, and moreover a degree of freedom in the arrangement of the first refrigeration cycle and the second refrigeration cycle is increased.

In an embodiment, the multi-refrigeration-cycle apparatus further comprises a cascade condenser configured to perform heat exchange between the first refrigerant and the second refrigerant.

According to the above-described embodiment, the cascade condenser serves both the condenser of the first refrigeration cycle and the evaporator of the second refrigeration cycle. As a result, the number of heat exchangers can be reduced and the installation area for the multi-refrigeration-cycle apparatus can be reduced.

In an embodiment, the first refrigeration cycle includes: a first evaporator configured to perform heat exchange between the cooling medium and the first refrigerant to generate the first refrigerant in a gas phase; a first compressor configured to compress the first refrigerant in the gas phase; a first condenser configured to condense the compressed first refrigerant in the gas phase to generate the first refrigerant in a liquid phase; and a heat exchanger disposed between the first compressor and the first condenser and configured to cool the compressed first refrigerant in the gas phase.

According to the above-described embodiment, the first refrigerant in the gas phase is cooled in advance before entering the first condenser. Therefore, a cooling calorie required in the first condenser is reduced. Specifically, the cooling calorie using the intermediate medium is reduced, and therefore a refrigerating capacity required for the second refrigeration cycle can be small. This leads to a reduction in power consumption of the second refrigeration cycle, and as a result, the operating efficiency of the multi-refrigeration-cycle apparatus can be improved. Further, since the refrigerating capacity of the second refrigeration cycle can be reduced, the installation area for the apparatus can be reduced. Moreover, the cooling liquid, such as cooling water or brine (antifreeze), used for cooling the first refrigerant in the gas phase is heated and discharged from the heat exchanger, so that the cooling water or brine (antifreeze) can be used for other application requiring heating, and power consumption for heating can be reduced.

In an embodiment, there is provided a multi-refrigeration-cycle apparatus for cooling a semiconductor-device manufacturing equipment, comprising: a first refrigeration cycle having a first refrigerant for performing heat exchange with a cooling medium for cooling the semiconductor-device manufacturing equipment, the first refrigerant circulating in the first refrigeration cycle; a second refrigeration cycle having a second refrigerant for performing heat exchange with the first refrigerant, the second refrigerant circulating in the second refrigeration cycle; and an intermediate-medium circulation line configured to circulate an intermediate medium between the first refrigeration cycle and the second refrigeration cycle.

In an embodiment, the intermediate-medium circulation line extends between a condenser of the first refrigeration cycle and an evaporator of the second refrigeration cycle.

In an embodiment, the multi-refrigeration-cycle apparatus further comprises a buffer tank coupled to the intermediate-medium circulation line.

In an embodiment, the intermediate medium is brine (antifreeze).

According to the above-described embodiments, the installation area for equipment installed in the sub-fab can be reduced. Moreover, the pipe for delivering the cooling medium to the semiconductor-device manufacturing equipment can be shortened. As a result, a space for the cooling pipe can be shortened, and the cooling efficiency can be improved.

According to the above-described embodiments, the intermediate medium can absorb the fluctuation of the temperature of the cooling medium that has been used for cooling the semiconductor-device manufacturing equipment, so that the operation of the multi-refrigeration-cycle apparatus can be stable. As a result, the multi-refrigeration-cycle apparatus can supply the cooling medium having a stable temperature to the semiconductor-device manufacturing equipment and appropriately cool the semiconductor-device manufacturing equipment.

### BRIEF DESCRIPTION OF THE DRAWINGS

FIG. 1 is a schematic diagram showing an embodiment of a multi-refrigeration-cycle apparatus for cooling a semiconductor-device manufacturing equipment;

FIG. 2 is a schematic diagram showing a detailed structure of an embodiment of a multi-refrigeration-cycle apparatus;

FIG. 3 is a schematic diagram showing a detailed structure of another embodiment of the multi-refrigeration-cycle apparatus;

FIG. 4 is a schematic diagram showing a detailed structure of still another embodiment of the multi-refrigeration-cycle apparatus;

FIG. 5 is a schematic diagram showing a detailed structure of still another embodiment of the multi-refrigeration-cycle apparatus;

FIG. 6 is a schematic diagram showing a detailed structure of still another embodiment of the multi-refrigeration-cycle apparatus;

FIG. 7 is a schematic diagram showing a detailed structure of an embodiment of a multi-refrigeration-cycle apparatus;

FIG. 8 is a schematic diagram showing a detailed structure of another embodiment of the multi-refrigeration-cycle apparatus;

FIG. 9 is a schematic diagram showing an embodiment of an arrangement of the multi-refrigeration-cycle apparatus; and

FIG. 10 is a schematic diagram for explaining a conventional arrangement of a semiconductor-device manufacturing equipment and a multi-refrigeration-cycle apparatus.

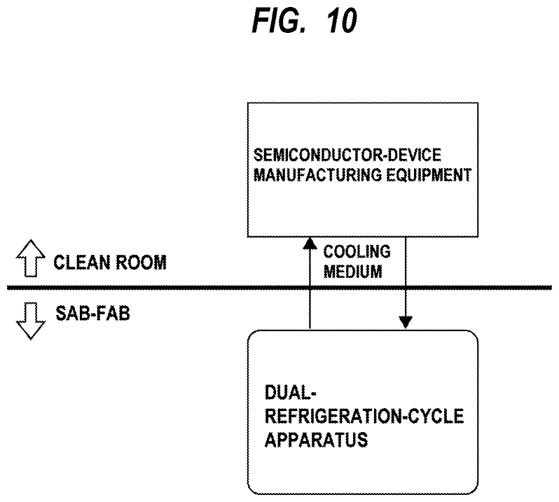

### DESCRIPTION OF EMBODIMENTS

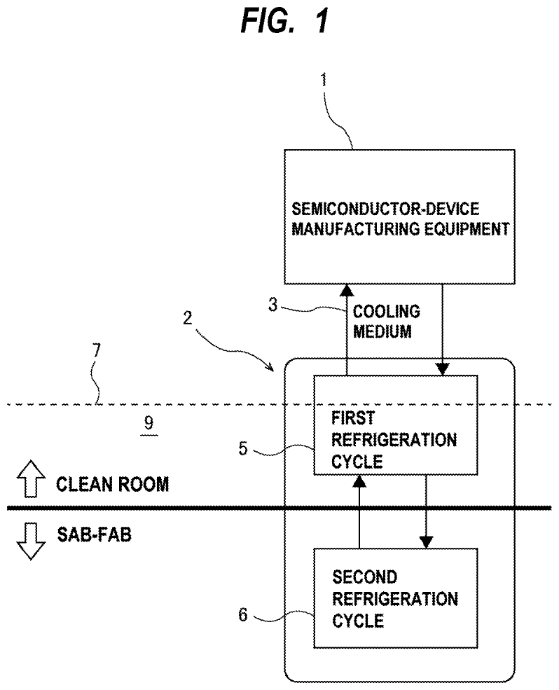

Hereinafter, embodiments will be described with reference to the drawings. FIG. 1 is a schematic diagram showing an embodiment of a multi-refrigeration-cycle apparatus for cooling a semiconductor-device manufacturing equipment. In the embodiment shown in FIG. 1, the semiconductor-device manufacturing equipment 1 is an etching equipment including a processing chamber. The semiconductor-device manufacturing equipment 1 is arranged in a clean room, and a part of a multi-refrigeration-cycle apparatus 2 is arranged in a sub-fab located under the clean room. The clean room is located upstairs and the sub-fab is located downstairs.

The multi-refrigeration-cycle apparatus 2 is coupled to the semiconductor-device manufacturing equipment 1 by a cooling pipe 3. The multi-refrigeration-cycle apparatus 2 delivers a cooling medium to the semiconductor-device manufacturing equipment 1 (for example, a processing chamber of the etching equipment) through the cooling pipe 3 to cool the semiconductor-device manufacturing equipment 1. The cooling medium circulates between the semiconductor-device manufacturing equipment 1 and the multi-refrigeration-cycle apparatus 2. Specifically, the cooling medium having a low temperature (for example, −30° C. to −120° C.) generated by the multi-refrigeration-cycle apparatus 2 is delivered to the semiconductor-device manufacturing equipment 1 through the cooling pipe 3 to cool the semiconductor-device manufacturing equipment 1. The cooling medium that has been used for cooling the semiconductor-device manufacturing equipment 1 is returned to the multi-refrigeration-cycle apparatus 2 through the cooling pipe 3.

The multi-refrigeration-cycle apparatus 2 includes a first refrigeration cycle 5 in which a first refrigerant for performing heat exchange with the cooling medium circulates, and a second refrigeration cycle 6 in which a second refrigerant for performing heat exchange with the first refrigerant circulates. Therefore, the multi-refrigeration-cycle apparatus 2 of the present embodiment is a dual-refrigeration-cycle apparatus. In one embodiment, the multi-refrigeration-cycle apparatus 2 may include three or more refrigeration cycles.

The entire first refrigeration cycle 5 is arranged in the clean room, and the entire second refrigeration cycle 6 is arranged in the sub-fab located downstairs under the clean room. A metal floor 7, such as grating, is arranged in the clean room, and there exists an underfloor space 9 under the floor 7. This underfloor space 9 is a part of the clean room. The semiconductor-device manufacturing equipment 1 is installed on the floor 7, and the first refrigeration cycle 5 is installed near the semiconductor-device manufacturing equipment 1, or in the underfloor space 9, etc.

According to the present embodiment, the first refrigeration cycle 5 and the second refrigeration cycle 6, which are components of the multi-refrigeration-cycle apparatus 2, are arranged in the clean room and the sub-fab, respectively. Therefore, the installation area for equipment in the sub-fab can be reduced. Further, according to the present embodiment, the first refrigeration cycle 5 is arranged in the clean room. This arrangement can shorten the cooling pipe 3 for delivering the cooling medium having an ultra-low temperature from the first refrigeration cycle 5 to the semiconductor-device manufacturing equipment 1 (for example, the processing chamber of the etching equipment). As a result, the space for the cooling pipe 3 can be reduced and the cooling efficiency can be improved.

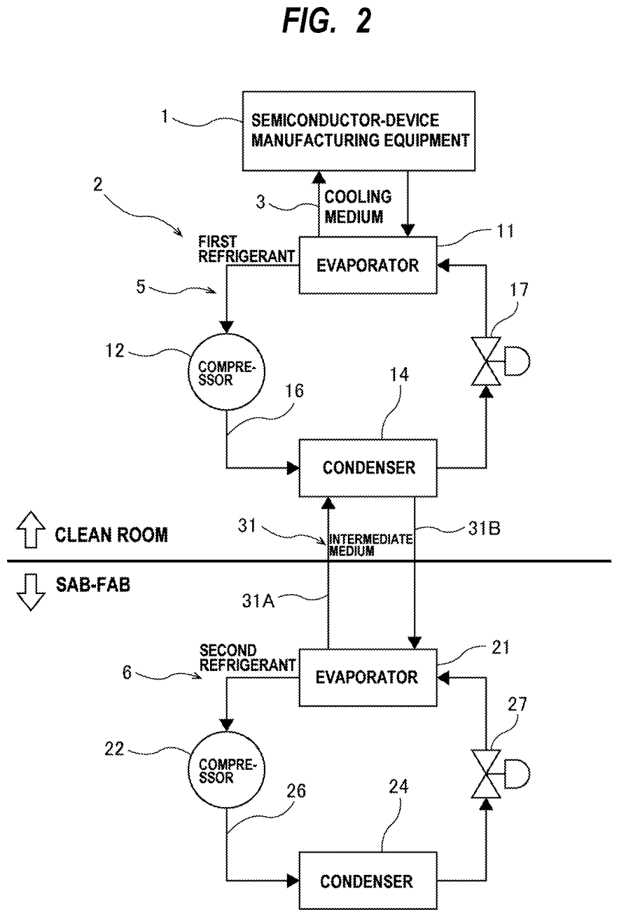

FIG. 2 is a schematic diagram showing a detailed structure of an embodiment of the multi-refrigeration-cycle apparatus 2. As shown in FIG. 2, the first refrigeration cycle 5 includes a first evaporator 11 configured to evaporate the first refrigerant in a liquid phase (i.e., refrigerant liquid) to generate the first refrigerant in a gas phase (i.e., refrigerant gas), a first compressor 12 configured to compress the first refrigerant in the gas phase, and a first condenser 14 configured to condense the compressed first refrigerant in the gas phase to generate the first refrigerant in the liquid phase. The first evaporator 11, the first compressor 12, and the first condenser 14 are coupled by a first refrigerant pipe 16. The first refrigerant circulates among the first evaporator 11, the first compressor 12, and the first condenser 14 through the first refrigerant pipe 16.

The first refrigeration cycle 5 further includes a first expansion valve 17 as a first expansion mechanism located between the first evaporator 11 and the first condenser 14. The first expansion valve 17 is attached to a portion of the first refrigerant pipe 16 extending between the first evaporator 11 and the first condenser 14. The first refrigerant, flowing from the first condenser 14 to the first evaporator 11, passes through the first expansion valve 17, so that pressure and temperature of the first refrigerant decrease. The first refrigerant that has passed through the first expansion valve 17 flows into the first evaporator 11.

The cooling pipe 3 is coupled to the first evaporator 11, and heat exchange between the cooling medium and the first refrigerant is performed in the first evaporator 11. As a result of this heat exchange, the cooling medium is cooled to a low temperature (for example, −30° C. to −120° C.), while the first refrigerant is heated by the cooling medium and evaporated into the refrigerant gas. The cooling medium that has been cooled is delivered through the cooling pipe 3 to the semiconductor-device manufacturing equipment 1, and the refrigerant gas is delivered to the first compressor 12 through the first refrigerant pipe 16. The first compressor 12 compresses the refrigerant gas and sends the compressed refrigerant gas to the first condenser 14. In the first condenser 14, as will be described later, the refrigerant gas is condensed into the refrigerant liquid.

The second refrigeration cycle 6 includes a second evaporator 21 configured to evaporate the second refrigerant in a liquid phase (i.e., refrigerant liquid) to generate the second refrigerant in a gas phase (i.e., refrigerant gas), a second compressor 22 configured to compress the second refrigerant in the gas phase, and a second condenser 24 configured to condense the compressed second refrigerant in the gas phase to generate the second refrigerant in the liquid phase. The second evaporator 21, the second compressor 22, and the second condenser 24 are coupled by a second refrigerant pipe 26. The second refrigerant circulates among the second evaporator 21, the second compressor 22, and the second condenser 24 through the second refrigerant pipe 26.

The multi-refrigeration-cycle apparatus 2 further includes an intermediate-medium circulation line 31 for circulating an intermediate medium between the first refrigeration cycle 5 and the second refrigeration cycle 6. The intermediate-medium circulation line 31 is coupled to the first refrigeration cycle 5 and the second refrigeration cycle 6. More specifically, the intermediate-medium circulation line 31 includes a feeding line 31A configured to deliver the intermediate medium from the second evaporator 21 of the second refrigeration cycle 6 to the first condenser 14 of the first refrigeration cycle 5, and a return line 31B for returning the intermediate medium from the first condenser 14 of the first refrigeration cycle 5 to the second evaporator 21 of the second refrigeration cycle 6. One end of the feeding line 31A is coupled to the first condenser 14, and the other end of the feeding line 31A is coupled to the second evaporator 21. One end of the return line 31B is coupled to the first condenser 14, and the other end of the return line 31B is coupled to the second evaporator 21.

The intermediate medium circulates through the intermediate-medium circulation line 31 between the first condenser 14 of the first refrigeration cycle 5 and the second evaporator 21 of the second refrigeration cycle 6. The first refrigerant in the gas phase (i.e., the refrigerant gas) and the intermediate medium perform the heat exchange in the first condenser 14. As a result, the first refrigerant in the gas phase is cooled by the intermediate medium into the first refrigerant in the liquid phase (i.e., the refrigerant liquid). The intermediate medium is heated by the first refrigerant, so that the temperature of the intermediate medium rises.

The intermediate medium heated by the first refrigerant and the second refrigerant in the liquid phase (i.e., the refrigerant liquid) perform the heat exchange in the second evaporator 21. As a result, the second refrigerant in the liquid phase is heated by the intermediate medium into the second refrigerant in the gas phase (i.e., the refrigerant gas), while the intermediate medium is cooled by the second refrigerant and the temperature of the intermediate medium drops. The cooled intermediate medium is delivered to the first condenser 14 of the first refrigeration cycle 5 through the intermediate-medium circulation line 31. The cooled intermediate medium and the first refrigerant perform the heat exchange in the first condenser 14. In this way, the intermediate medium circulates through the intermediate-medium circulation line 31 between the first condenser 14 of the first refrigeration cycle 5 and the second evaporator 21 of the second refrigeration cycle 6. The temperature of the intermediate medium flowing from the second evaporator 21 to the first condenser 14 is in a range of, for example, 0° C. to −80° C.

In the second evaporator 21, the second refrigerant is heated by the intermediate medium and evaporated into the refrigerant gas. This refrigerant gas is delivered to the second compressor 22 through the second refrigerant pipe 26. The second compressor 22 compresses the refrigerant gas and sends the compressed refrigerant gas to the second condenser 24. In the second condenser 24, heat exchange is performed between cooling water supplied from a cooling-water source (not shown) and the refrigerant gas (second refrigerant in the gas phase). As a result, the refrigerant gas is condensed into the refrigerant liquid.

As described above, the first refrigerant in the first refrigeration cycle 5 and the second refrigerant in the second refrigeration cycle 6 perform the heat exchange via the intermediate medium. The intermediate medium is a liquid of a type different from the first refrigerant and the second refrigerant. More specifically, the intermediate medium may be a brine (or an antifreeze liquid), such as a perfluorocarbon (PFG) liquid or an ethylene glycol liquid. Therefore, the intermediate medium circulates as it is in the liquid phase in the intermediate-medium circulation line 31.

The brine (or antifreeze liquid), which is easier to handle than the first refrigerant and the second refrigerant, can be used as the intermediate medium as long as the heat of the first refrigerant can be transferred to the second refrigerant. Therefore, a flexible and inexpensive pipe, such as resin tube, can be used for the intermediate-medium circulation line 31. As a result, a manufacturing cost can be reduced, and moreover a degree of freedom in the arrangement of the first refrigeration cycle 5 and the second refrigeration cycle 6 is increased. Further, since the temperature of the intermediate medium (for example, 0° C. to −80° C.) is higher than the temperature of the refrigerant (for example, −30° C. to −120° C.), a cold insulating material covering the medium circulation line 31 may be a simple one, as compared with a cold insulating material covering the cooling pipe 3.

The intermediate medium has a thermal capacity corresponding to its volume. Therefore, the intermediate medium functions as a thermal buffer between the first refrigerant and the second refrigerant. Generally, the temperature of the cooling medium that has been used for cooling the semiconductor-device manufacturing equipment 1 varies, and the temperature of the first refrigerant tends to fluctuate accordingly. Since the intermediate medium can absorb such fluctuations of the temperature of the first refrigerant, the operation of the multi-refrigeration-cycle apparatus 2 can be stable. As a result, the multi-refrigeration-cycle apparatus 2 can supply the cooling medium having a stable temperature to the semiconductor-device manufacturing equipment 1.

The second refrigeration cycle 6 further includes a second expansion valve 27 as a second expansion mechanism located between the second evaporator 21 and the second condenser 24. The second expansion valve 27 is attached to a portion of the second refrigerant pipe 26 extending between the second evaporator 21 and the second condenser 24. The second refrigerant flowing from the second condenser 24 to the second evaporator 21 passes through the second expansion valve 27, so that pressure and temperature of the second refrigerant decrease. The second refrigerant that has passed through the second expansion valve 27 flows into the second evaporator 21.

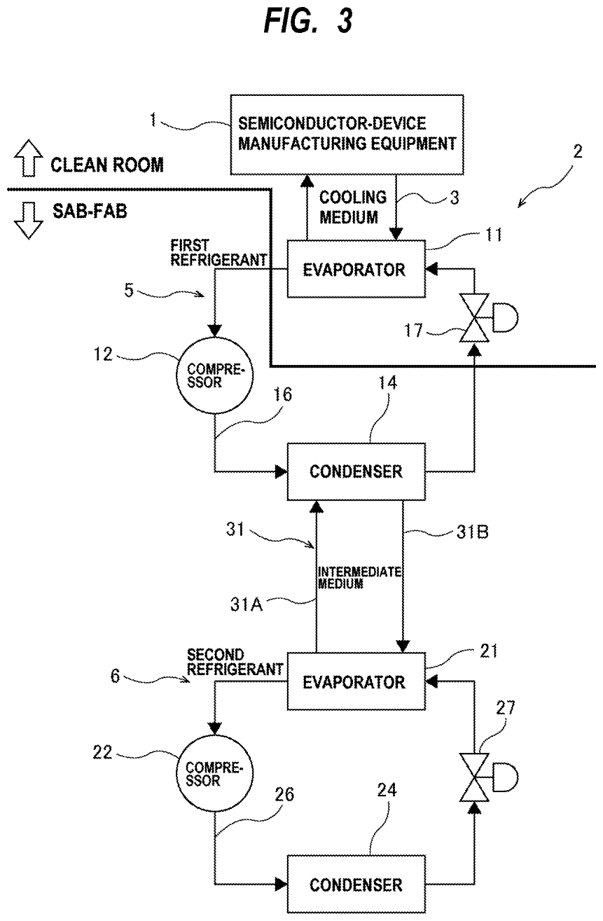

FIG. 3 is a schematic diagram showing a detailed structure of still another embodiment of the multi-refrigeration-cycle apparatus 2. Configurations and operations of the present embodiment, which will not be particularly described, are the same as those of the embodiments described with reference to FIGS. 1 and 2, and duplicate descriptions thereof will be omitted. In the embodiment shown in FIG. 3, a part of the first refrigeration cycle 5 is located in the clean room, and other part of the first refrigeration cycle 5 is located in the sub-fab. In this embodiment, the first evaporator 11 and the first expansion valve 17 are arranged in the clean room, and the first compressor 12 and the first condenser 14 are arranged in the sub-fab. The entire intermediate-medium circulation line 31 is also arranged in the sub-fab.

This embodiment is advantageous when the installation area of the clean room is small. Further, according to the present embodiment, the first compressor 12 and the first condenser 14 are arranged in the sub-fab downstairs, and the first evaporator 11 is arranged in the clean room upstairs. Therefore, a lubricating oil that has leaked from the first compressor 12 into the first refrigerant does not stay in the first evaporator 11, and the lubricating oil can be returned to the first compressor 12 by its gravity. Further, the first evaporator 11 and the first expansion valve 17 of the first refrigeration cycle 5, which are components each having a low temperature, are arranged in the clean room. This arrangement can shorten the cooling pipe 3 for delivering the cooling medium from the first refrigeration cycle 5 to the semiconductor-device manufacturing equipment 1.

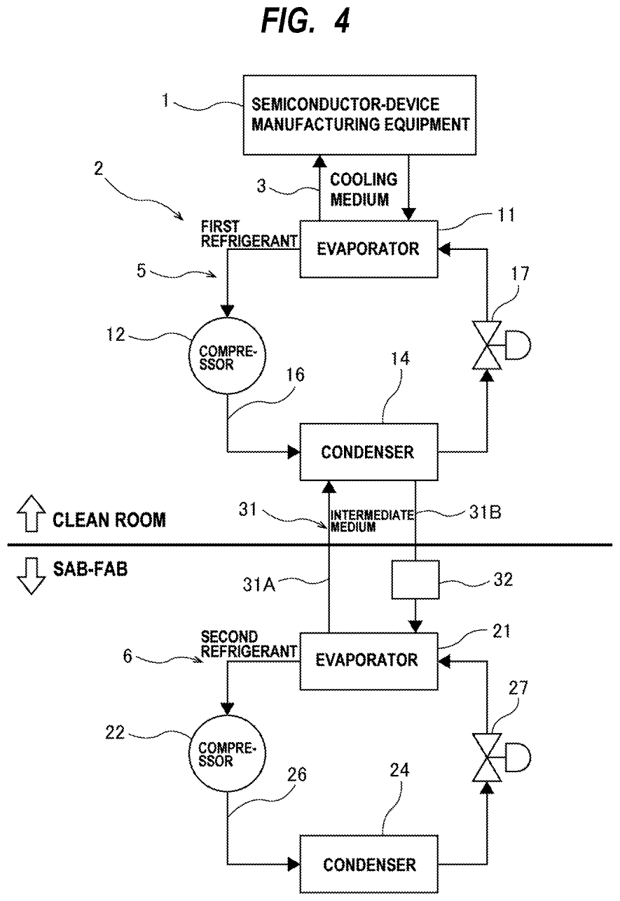

As shown in FIG. 4, in one embodiment, the multi-refrigeration-cycle apparatus 2 may further include a buffer tank 32 coupled to the intermediate-medium circulation line 31. In the embodiment shown in FIG. 4, the buffer tank 32 is coupled to the return line 31B for returning the intermediate medium from the first condenser 14 of the first refrigeration cycle 5 to the second evaporator 21 of the second refrigeration cycle 6. The buffer tank 32 is arranged in the sub-fab having a sufficient installation area. The intermediate medium leaving the first condenser 14 of the first refrigeration cycle 5 is temporarily stored in the buffer tank 32, and then returned from the buffer tank 32 to the second evaporator 21 of the second refrigeration cycle 6.

According to the present embodiment, the volume of the intermediate medium is increased by the volume of the buffer tank 32. Therefore, the thermal capacity of the intermediate medium is increased, and the operation of the multi-refrigeration-cycle apparatus 2 can be more stable. The buffer tank 32 shown in FIG. 4 may be incorporated into the embodiment of FIG. 3.

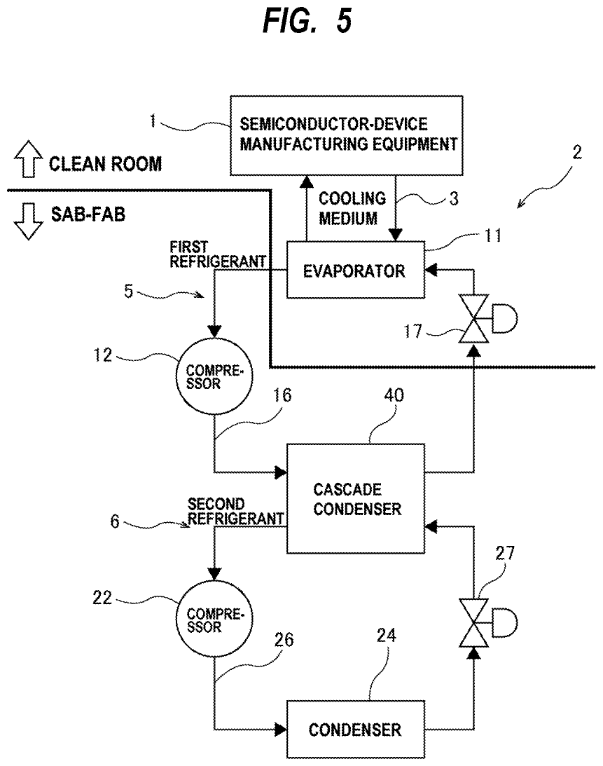

FIG. 5 is a schematic diagram showing a detailed structure of still another embodiment of the multi-refrigeration-cycle apparatus 2. Configurations and operations of the present embodiment, which will not be particularly described, are the same as those of the embodiment described with reference to FIG. 2, and duplicate descriptions thereof will be omitted. In the embodiment shown in FIG. 5, the condenser of the first refrigeration cycle 5 and the evaporator of the second refrigeration cycle 6 are composed of a common cascade condenser 40. The cascade condenser 40 is a heat exchanger in which the condenser of the first refrigeration cycle 5 serves as the evaporator of the second refrigeration cycle 6. The cascade condenser 40 is arranged in the sub-fab. In one embodiment, if the installation area in the clean room is sufficient, the first evaporator 11, the first compressor 12, and the first expansion valve 17 of the first refrigeration cycle 5, and the cascade condenser 40 may be arranged in the clean room.

In this embodiment, the intermediate-medium circulation line 31 is not provided. Both the first refrigerant pipe 16 of the first refrigeration cycle 5 and the second refrigerant pipe 26 of the second refrigeration cycle 6 are coupled to the cascade condenser 40. The first refrigerant that circulates in the first refrigeration cycle 5 and the second refrigerant that circulates in the second refrigeration cycle 6 flow through the cascade condenser 40, and the heat exchange between the first refrigerant and the second refrigerant is performed in the cascade condenser 40. Since the cascade condenser 40 serves as both the condenser of the first refrigeration cycle 5 and the evaporator of the second refrigeration cycle 6, the number of heat exchangers can be reduced, and the installation area of the multi-refrigeration-cycle apparatus 2 can be reduced.

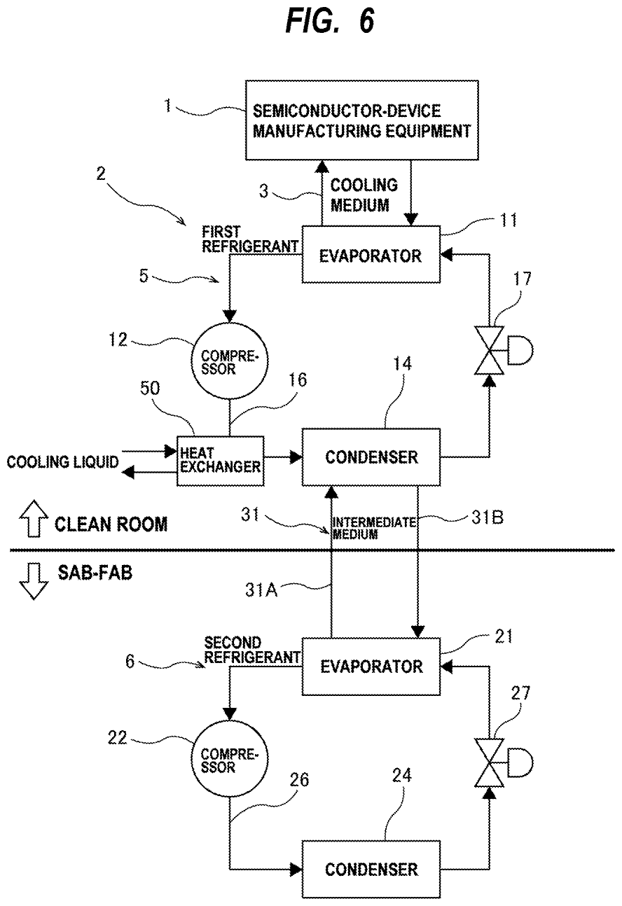

FIG. 6 is a schematic diagram showing a detailed structure of still another embodiment of the multi-refrigeration-cycle apparatus 2. Configurations and operations of the present embodiment, which will not be particularly described, are the same as those of the embodiment described with reference to FIG. 2, and duplicate descriptions thereof will be omitted. In this embodiment, a heat exchanger 50 is installed between the first compressor 12 and the first condenser 14 in the first refrigeration cycle 5. The heat exchanger 50 is coupled to a portion of the first refrigerant pipe 16 extending between the first compressor 12 and the first condenser 14. A cooling liquid, such as cooling water or brine (antifreeze liquid), and the compressed first refrigerant in the gas phase flow through the heat exchanger 50, so that heat exchange is performed between the cooling liquid and the first refrigerant in the gas phase. The first refrigerant in the gas phase cooled by the heat exchange with the cooling liquid is introduced to the first condenser 14.

As described above, the first refrigerant in the gas phase is cooled in advance before entering the first condenser 14. Therefore, a cooling calorie required in the first condenser 14 is reduced. Specifically, the cooling calorie using the intermediate medium is reduced, and therefore a refrigerating capacity required for the second refrigeration cycle 6 can be small. This leads to a reduction in power consumption of the second refrigeration cycle 6, and as a result, the operating efficiency of the multi-refrigeration-cycle apparatus 2 can be improved. Further, since the refrigerating capacity of the second refrigeration cycle 6 can be reduced, the installation area for the apparatus can be reduced. Moreover, the cooling liquid, such as cooling water or brine (antifreeze), used for cooling the first refrigerant in the gas phase is heated and discharged from the heat exchanger 50, so that the cooling liquid can be used for other application requiring heating, and power consumption for heating can be reduced.

The heat exchanger 50 can be applied to the embodiments described with reference to FIGS. 3 to 5. For example, the heat exchanger 50 may be arranged between the first compressor 12 and the cascade condenser 40 shown in FIG. 5.

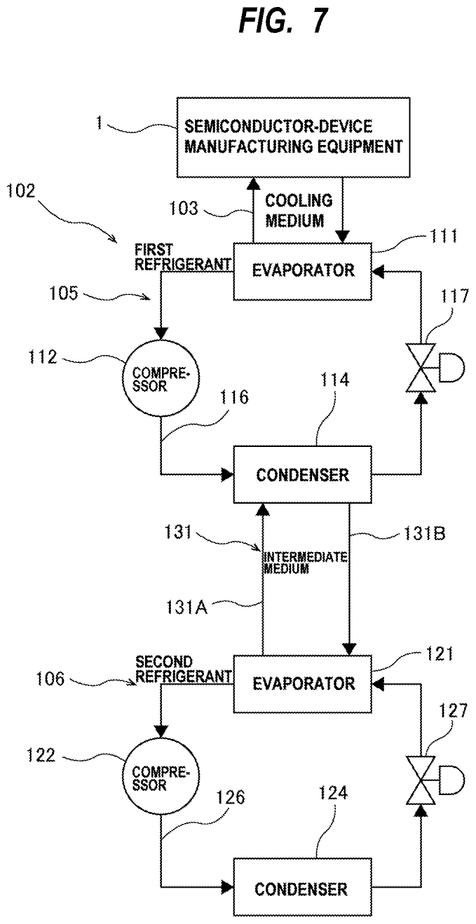

FIG. 7 is a schematic diagram showing a detailed structure of an embodiment of a multi-refrigeration-cycle apparatus 102. As shown in FIG. 7, the multi-refrigeration-cycle apparatus 102 is coupled to the semiconductor-device manufacturing equipment 1 by a cooling pipe 103. The multi-refrigeration-cycle apparatus 102 delivers a cooling medium to the semiconductor-device manufacturing equipment 1 (for example, a processing chamber of an etching equipment) through the cooling pipe 103 to cool the semiconductor-device manufacturing equipment 1. The cooling medium circulates between the semiconductor-device manufacturing equipment 1 and the multi-refrigeration-cycle apparatus 102. Specifically, the cooling medium having a low temperature (for example, −30° C. to −120° C.) generated by the multi-refrigeration-cycle apparatus 102 is delivered to the semiconductor-device manufacturing equipment 1 through the cooling pipe 103 to cool the semiconductor-device manufacturing equipment 1. The cooling medium that has been used for cooling the semiconductor-device manufacturing equipment 1 is returned to the multi-refrigeration-cycle apparatus 102 through the cooling pipe 103.

The multi-refrigeration-cycle apparatus 102 includes a first refrigeration cycle 105 in which a first refrigerant for performing heat exchange with the cooling medium circulates, and a second refrigeration cycle 106 in which a second refrigerant for performing heat exchange with the first refrigerant via an intermediate medium circulates. Therefore, the multi-refrigeration-cycle apparatus 102 of the present embodiment is a dual-refrigeration-cycle apparatus. In one embodiment, the multi-refrigeration-cycle apparatus 102 may include three or more refrigeration cycles.

The first refrigeration cycle 105 includes a first evaporator 111 configured to evaporate the first refrigerant in a liquid phase (i.e., refrigerant liquid) to generate the first refrigerant in a gas phase (i.e., refrigerant gas), a first compressor 112 configured to compress the first refrigerant in the gas phase, and a first condenser 114 configured to condense the compressed first refrigerant in the gas phase to generate the first refrigerant in the liquid phase. The first evaporator 111, the first compressor 112, and the first condenser 114 are coupled by a first refrigerant pipe 116. The first refrigerant circulates among the first evaporator 111, the first compressor 112, and the first condenser 114 through the first refrigerant pipe 116.

The first refrigeration cycle 105 further includes a first expansion valve 117 as a first expansion mechanism located between the first evaporator 111 and the first condenser 114. The first expansion valve 117 is attached to a portion of the first refrigerant pipe 116 extending between the first evaporator 111 and the first condenser 114. The first refrigerant flowing from the first condenser 114 to the first evaporator 111 passes through the first expansion valve 117, so that pressure and temperature of the first refrigerant decrease. The first refrigerant that has passed through the first expansion valve 117 flows into the first evaporator 111.

The cooling pipe 103 is coupled to the first evaporator 111, and heat exchange between the cooling medium and the first refrigerant is performed in the first evaporator 111. As a result of this heat exchange, the cooling medium is cooled to a low temperature (for example, −30° C. to −120° C.), while the first refrigerant is heated by the cooling medium and evaporated into refrigerant gas. The cooling medium that has been cooled is delivered to the semiconductor-device manufacturing equipment 1 through the cooling pipe 103, and the refrigerant gas is delivered to the first compressor 112 through the first refrigerant pipe 116. The first compressor 112 compresses the refrigerant gas and sends the compressed refrigerant gas to the first condenser 114. In the first condenser 114, as will be described later, the refrigerant gas is condensed into the refrigerant liquid.

The second refrigeration cycle 106 includes a second evaporator 121 configured to evaporate the second refrigerant in a liquid phase (i.e., refrigerant liquid) to generate the second refrigerant in a gas phase (i.e., refrigerant gas), a second compressor 122 configured to compress the second refrigerant in the gas phase, and a second condenser 124 configured to condense the compressed second refrigerant in the gas phase to generate the second refrigerant in the liquid phase. The second evaporator 121, the second compressor 122, and the second condenser 124 are coupled by a second refrigerant pipe 126. The second refrigerant circulates among the second evaporator 121, the second compressor 122, and the second condenser 124 through the second refrigerant pipe 126.

The multi-refrigeration-cycle apparatus 102 further includes an intermediate-medium circulation line 131 for circulating the intermediate medium between the first refrigeration cycle 105 and the second refrigeration cycle 106. The intermediate-medium circulation line 131 is coupled to the first refrigeration cycle 105 and the second refrigeration cycle 106. More specifically, the intermediate-medium circulation line 131 includes a feeding line 131A configured to deliver the intermediate medium from the second evaporator 121 of the second refrigeration cycle 106 to the first condenser 114 of the first refrigeration cycle 105, and a return line 131B for returning the intermediate medium from the first condenser 114 of the first refrigeration cycle 105 to the second evaporator 121 of the second refrigeration cycle 106. One end of the feeding line 131A is coupled to the first condenser 114, and the other end of the feeding line 131A is coupled to the second evaporator 121. One end of the return line 131B is coupled to the first condenser 114, and the other end of the return line 131B is coupled to the second evaporator 121.

The intermediate medium circulates through the intermediate-medium circulation line 131 between the first condenser 114 of the first refrigeration cycle 105 and the second evaporator 121 of the second refrigeration cycle 106. The first refrigerant in the gas phase (i.e., the refrigerant gas) and the intermediate medium perform the heat exchange in the first condenser 114. As a result, the first refrigerant in the gas phase is cooled by the intermediate medium into the first refrigerant in the liquid phase (i.e., the refrigerant liquid). The intermediate medium is heated by the first refrigerant, so that the temperature of the intermediate medium rises.

The intermediate medium heated by the first refrigerant and the second refrigerant in the liquid phase (i.e., the refrigerant liquid) perform the heat exchange in the second evaporator 121. As a result, the second refrigerant in the liquid phase is heated by the intermediate medium into the second refrigerant in the gas phase (i.e., the refrigerant gas), while the intermediate medium is cooled by the second refrigerant and the temperature of the intermediate medium drops. The cooled intermediate medium is delivered to the first condenser 114 of the first refrigeration cycle 105 through the intermediate-medium circulation line 131. The cooled intermediate medium and the first refrigerant perform the heat exchange in the first condenser 114. In this way, the intermediate medium circulates through the intermediate-medium circulation line 131 between the first condenser 114 of the first refrigeration cycle 105 and the second evaporator 121 of the second refrigeration cycle 106. The temperature of the intermediate medium flowing from the second evaporator 121 to the first condenser 114 is in a range of, for example, 0° C. to −80° C.

In the second evaporator 121, the second refrigerant is heated by the intermediate medium and evaporated into the refrigerant gas. This refrigerant gas is delivered to the second compressor 122 through the second refrigerant pipe 126. The second compressor 122 compresses the refrigerant gas and sends the compressed refrigerant gas to the second condenser 124. In the second condenser 124, heat exchange is performed between cooling water supplied from a cooling-water source (not shown) and the refrigerant gas (second refrigerant in the gas phase). As a result, the refrigerant gas is condensed into the refrigerant liquid.

As described above, the first refrigerant in the first refrigeration cycle 105 and the second refrigerant in the second refrigeration cycle 106 perform the heat exchange via the intermediate medium. The intermediate medium is a liquid of a type different from the first refrigerant and the second refrigerant. More specifically, the intermediate medium may be a brine (or an antifreeze liquid), such as a perfluorocarbon (PFC) liquid or an ethylene glycol liquid. Therefore, the intermediate medium circulates as it is in the liquid phase in the intermediate-medium circulation line 131.

The brine (or antifreeze liquid), which is easier to handle than the first refrigerant and the second refrigerant, can be used as the intermediate medium as long as the heat of the first refrigerant can be transferred to the second refrigerant. Therefore, a flexible and inexpensive pipe, such as resin tube, can be used for the intermediate-medium circulation line 131. As a result, a manufacturing cost can be reduced, and moreover a degree of freedom in the arrangement of the first refrigeration cycle 105 and the second refrigeration cycle 106 is increased. Further, since the temperature of the intermediate medium (for example, 0° C. to −80° C.) is higher than the temperature of the refrigerant (for example, −30° C. to −120° C.), a cold insulating material covering the medium circulation line 131 may be a simple one, as compared with a cold insulating material covering the cooling pipe 103.

The intermediate medium has a thermal capacity corresponding to its volume. Therefore, the intermediate medium functions as a thermal buffer between the first refrigerant and the second refrigerant. Generally, the temperature of the cooling medium that has been used for cooling the semiconductor-device manufacturing equipment 1 varies, and the temperature of the first refrigerant tends to fluctuate accordingly. Since the intermediate medium can absorb such fluctuations of the temperature of the first refrigerant, the operation of the multi-refrigeration-cycle apparatus 102 can be stable. As a result, the multi-refrigeration-cycle apparatus 102 can supply the cooling medium having a stable temperature to the semiconductor-device manufacturing equipment 1.

The second refrigeration cycle 106 further includes a second expansion valve 127 as a second expansion mechanism located between the second evaporator 121 and the second condenser 124. The second expansion valve 127 is attached to a portion of the second refrigerant pipe 126 extending between the second evaporator 121 and the second condenser 124. The second refrigerant flowing from the second condenser 124 to the second evaporator 121 passes through the second expansion valve 127, so that pressure and temperature of the second refrigerant decrease. The second refrigerant that has passed through the second expansion valve 127 flows into the second evaporator 121.

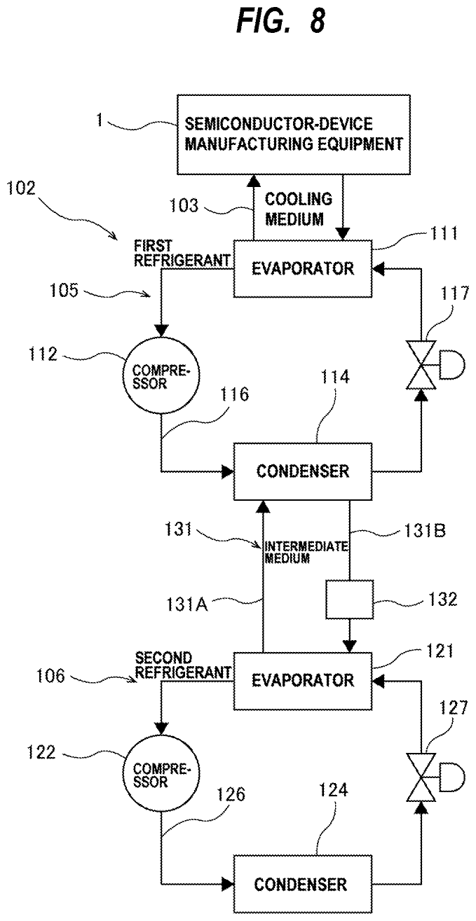

As shown in FIG. 8, in one embodiment, the multi-refrigeration-cycle apparatus 102 may further include a buffer tank 132 coupled to the intermediate-medium circulation line 131. In the embodiment shown in FIG. 8, the buffer tank 132 is coupled to the return line 131B for returning the intermediate medium from the first condenser 114 of the first refrigeration cycle 105 to the second evaporator 121 of the second refrigeration cycle 106. The buffer tank 132 is arranged in an area called a sub-fab, which is a sub-fabrication in which various peripheral devices are installed. The sub-fab has a sufficient installation area. The intermediate medium leaving the first condenser 114 of the first refrigeration cycle 105 is temporarily stored in the buffer tank 132, and then returned from the buffer tank 132 to the second evaporator 121 of the second refrigeration cycle 106.

According to the present embodiment, the volume of the intermediate medium is increased by the volume of the buffer tank 132. Therefore, the thermal capacity of the intermediate medium is increased, and the operation of the multi-refrigeration-cycle apparatus 2 can be more stable.

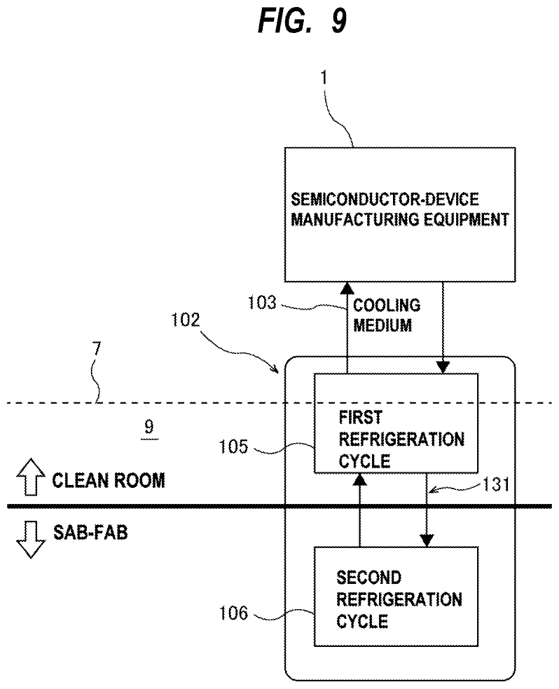

FIG. 9 is a schematic diagram showing an embodiment of an arrangement of the multi-refrigeration-cycle apparatus. The semiconductor-device manufacturing equipment 1 (for example, the processing chamber of the etching equipment) is arranged in a clean room, and a part of the multi-refrigeration-cycle apparatus 102 is arranged in a sub-fab existing under the clean room. Generally, the clean room is located upstairs and the sub-fab is located downstairs.

The entire first refrigeration cycle 105 is located in the clean room, and the entire second refrigeration cycle 106 is located in the sub-fab located downstairs under the clean room. A metal floor 7, such as grating, is arranged in the clean room, and there exists an underfloor space 9 under the floor 7. This underfloor space 9 is a part of the clean room. The semiconductor-device manufacturing equipment 1 is installed on the floor 7, and the first refrigeration cycle 105 is installed near the semiconductor-device manufacturing equipment 1, or in the underfloor space 9, etc.

The intermediate-medium circulation line 131 can increase the degree of freedom in the arrangement of the first refrigeration cycle 105 and the second refrigeration cycle 106. Therefore, as shown in FIG. 9, the first refrigeration cycle 105 and the second refrigeration cycle 106, which are components of the multi-refrigeration-cycle apparatus 102, can be arranged in the clean room and the sub-fab, respectively. As a result, the installation area for the equipment installed in the sub-fab can be reduced. Further, according to the present embodiment, the first refrigeration cycle 105 is arranged in the clean room. This arrangement can shorten the cooling pipe 103 for delivering the cooling medium having an ultra-low temperature from the first refrigeration cycle 105 to the semiconductor-device manufacturing equipment 1 (for example, the processing chamber of the etching equipment). As a result, the space for the cooling pipe 103 can be reduced and the cooling efficiency can be improved.

Furthermore, the intermediate-medium circulation line 131 makes it possible to couple one second refrigeration cycle to a plurality of first refrigeration cycles. As a result, the installation area for equipment in the sub-fab can be reduced, and the operation efficiency can be improved.

In addition, the intermediate-medium circulation line 131 further makes it possible to add a second refrigeration cycle relatively easily even after the operation of the apparatus is started. Therefore, the multi-refrigeration-cycle apparatus 102 can flexibly respond to the change (increase) in the cooling capacity and the change (decrease) in the cooling temperature.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A multi-refrigeration-cycle apparatus for cooling a semiconductor-device manufacturing equipment, comprising:
a first refrigeration cycle having a first refrigerant for performing heat exchange with a cooling medium for cooling the semiconductor-device manufacturing equipment, the first refrigerant circulating in the first refrigeration cycle; and
a second refrigeration cycle having a second refrigerant for performing heat exchange with the first refrigerant, the second refrigerant circulating in the second refrigeration cycle,
wherein at least a part of the first refrigeration cycle is arranged in a clean room where the semiconductor-device manufacturing equipment is installed, and
the second refrigeration cycle is arranged in a sub-fab.

2. The multi-refrigeration-cycle apparatus according to claim 1, wherein the entire first refrigeration cycle is arranged in the clean room.

3. The multi-refrigeration-cycle apparatus according to claim 1, wherein the first refrigeration cycle includes:
a first evaporator configured to perform heat exchange between the cooling medium and the first refrigerant to generate the first refrigerant in a gas phase;
a first compressor configured to compress the first refrigerant in the gas phase;
a first condenser configured to condense the compressed first refrigerant in the gas phase to generate the first refrigerant in a liquid phase; and
a first expansion mechanism located between the first condenser and the first evaporator and configured to reduce pressure and temperature of the first refrigerant,
the first evaporator and the first expansion mechanism are arranged in the clean room, and the first compressor and the first condenser are arranged in the sub-fab.

4. The multi-refrigeration-cycle apparatus according to claim 1, further comprising an intermediate-medium circulation line configured to circulate an intermediate medium between the first refrigeration cycle and the second refrigeration cycle, the intermediate-medium circulation line extending between the first refrigeration cycle and the second refrigeration cycle.

5. The multi-refrigeration-cycle apparatus according to claim 4, further comprising a buffer tank coupled to the intermediate-medium circulation line.

6. The multi-refrigeration-cycle apparatus according to claim 4, wherein the intermediate medium is brine (antifreeze).

7. The multi-refrigeration-cycle apparatus according to claim 1, further comprising a cascade condenser configured to perform heat exchange between the first refrigerant and the second refrigerant.

8. The multi-refrigeration-cycle apparatus according to claim 1, wherein the first refrigeration cycle includes:
a first evaporator configured to perform heat exchange between the cooling medium and the first refrigerant to generate the first refrigerant in a gas phase;
a first compressor configured to compress the first refrigerant in the gas phase;
a first condenser configured to condense the compressed first refrigerant in the gas phase to generate the first refrigerant in a liquid phase; and
a heat exchanger disposed between the first compressor and the first condenser and configured to cool the compressed first refrigerant in the gas phase.

9. A multi-refrigeration-cycle apparatus for cooling a semiconductor-device manufacturing equipment, comprising:
a first refrigeration cycle having a first refrigerant for performing heat exchange with a cooling medium for cooling the semiconductor-device manufacturing equipment, the first refrigerant circulating in the first refrigeration cycle;
a second refrigeration cycle having a second refrigerant for performing heat exchange with the first refrigerant, the second refrigerant circulating in the second refrigeration cycle; and
an intermediate-medium circulation line configured to circulate an intermediate medium between the first refrigeration cycle and the second refrigeration cycle.

10. The multi-refrigeration-cycle apparatus according to claim 9, wherein the intermediate-medium circulation line extends between a condenser of the first refrigeration cycle and an evaporator of the second refrigeration cycle.

11. The multi-refrigeration-cycle apparatus according to claim 9, further comprising a buffer tank coupled to the intermediate-medium circulation line.

12. The multi-refrigeration-cycle apparatus according to claim 9, wherein the intermediate medium is brine (antifreeze).
